(19) United States
(12) Patent Application Publication
(10) Pub. No.: US 2026/0129958 A1
(43) Pub. Date: May 7, 2026

(54) SILICON CARBIDE MOSFET WITH INTEGRATED POLYSILICON-SILICON CARBIDE HETEROJUNCTION DIODE

(71) Applicant: Renesas Electronics Corporation, Tokyo (JP)

(72) Inventors: Meng Chia LEE, Dallas, TX (US); Dilip Madhav RISBUD, San Jose, CA (US)

(73) Assignee: Renesas Electronics Corporation, Tokyo (JP)

(21) Appl. No.: 18/937,491

(22) Filed: Nov. 5, 2024

(51) Int. Cl. H01L 29/78; H01L 29/16; H01L 29/47; H01L 29/66; H01L 29/872

(52) U.S. Cl. CPC H10D 84/146; H10D 8/605; H10D 62/8325; H10D 64/64; H10D 8/051; H10D 12/031; H10D 30/0291

(57) ABSTRACT

A semiconductor structure includes a semiconductor substrate of a first conductivity type. The semiconductor substrate can have an upper surface and a bottom surface. The semiconductor substrate can be made of polycrystalline silicon carbide. The semiconductor structure can further include a drift region of the first conductivity type located on the upper surface of the semiconductor substrate. The semiconductor structure can further include a first region of the upper surface of the semiconductor substrate including a formation region of a transistor, and a second region of the upper surface of the semiconductor substrate, adjacent to the first region, including a formation region of a Schottky barrier diode.

### BACKGROUND

The present invention generally relates to the field of semiconductor devices, and more particularly to silicon carbide metal-oxide semiconductor field effect transistors.

Despite having similar design elements, silicon carbide (SiC) metal-oxide-semiconductor field-effect transistors (MOSFETs) have a higher blocking voltage and higher thermal conductivity than silicon (Si) MOSFETs. SiC MOSFETs are used in medium-to high-voltage power systems since they can enable higher switching frequencies with improved efficiency while reducing the system size and the need for redundancy.

### SUMMARY

According to an embodiment of the present disclosure, a semiconductor structure can include a semiconductor substrate of a first conductivity type. The semiconductor substrate can have an upper surface and a bottom surface. The semiconductor substrate can be formed by polycrystalline silicon carbide. The semiconductor structure can further include a drift region of the first conductivity type located on the upper surface of the semiconductor substrate. The semiconductor structure can further include a first region of the upper surface of the semiconductor substrate including a formation region of a transistor. The semiconductor structure can further include a second region of the upper surface of the semiconductor substrate, adjacent to the first region, including a formation region of a Schottky barrier diode.

According to another embodiment of the present disclosure, a semiconductor structure can include a drift region of a first conductivity type located on an upper surface of a semiconductor substrate of the first conductivity type. The drift region and the semiconductor substrate can include polycrystalline silicon carbide. The semiconductor structure can further include a JFET region of the first conductivity type disposed above the drift region. The JFET region can include a vertical portion and a horizontal portion. The semiconductor structure can further include a pair of channel regions disposed along the vertical portion and the horizontal portion of the JFET region. The semiconductor structure can further include a pair of source regions adjacent to the JFET region. Each source region can be abutted by a respective channel region and a first doped semiconductor region. The semiconductor structure can further include a Schottky electrode adjacent to the first doped semiconductor region, wherein an oxide layer electrically separates the Schottky electrode from the first doped semiconductor region, wherein the oxide layer covers vertical opposing sidewalls of the Schottky electrode and a gap located on a bottom portion of the oxide layer allows the Schottky electrode to contact a second doped semiconductor region located within the drift region.

According to yet another embodiment of the present disclosure, a semiconductor structure can include a drift region of a first conductivity type located on an upper surface of a semiconductor substrate of the first conductivity type. The drift region and the semiconductor substrate can include polycrystalline silicon carbide. The semiconductor structure can further include a trench extending into the drift region and a polysilicon layer disposed within the trench. The semiconductor structure can further include an oxide layer disposed on opposing vertical sidewalls of the polysilicon layer and between an upper part of the polysilicon layer and a lower part of the polysilicon layer. A bottom portion of the oxide layer can include a gap. The semiconductor structure can further include a doped semiconductor region within the drift region. The gap on the bottom portion of the oxide layer can allow the lower part of the polysilicon layer to contact the doped semiconductor region.

### BRIEF DESCRIPTION OF THE DRAWINGS

The following detailed description, given by way of example and not intended to limit the invention solely thereto, will best be appreciated in conjunction with the accompanying drawings, in which:

FIG. 1 is a cross-sectional view of a semiconductor structure at an intermediate step during a semiconductor manufacturing process, according to an embodiment of the present disclosure;

FIG. 2 is a cross-sectional view of the semiconductor structure after forming an oxide layer within a trench, according to an embodiment of the present disclosure;

FIG. 3 is a cross-sectional view of the semiconductor structure after forming a nitride layer above the oxide layer, according to an embodiment of the present disclosure;

FIG. 4 is a cross-sectional view of the semiconductor structure after forming a photoresist layer, according to an embodiment of the present disclosure;

FIG. 5 is a cross-sectional view of the semiconductor structure after patterning the photoresist layer and etching the nitride layer, according to an embodiment of the present disclosure;

FIG. 6 is a cross-sectional view of the semiconductor structure after removing a bottom portion of the oxide layer, according to an embodiment of the present disclosure;

FIG. 7 is a cross-sectional view of the semiconductor structure after stripping the nitride layer, according to an embodiment of the present disclosure;

FIG. 8 is a cross-sectional view of the semiconductor structure after forming a polysilicon layer within the trench, according to an embodiment of the present disclosure;

FIG. 9 is a cross-sectional view of the semiconductor structure after patterning the polysilicon layer to form a gate electrode, according to an embodiment of the present disclosure;

FIG. 10 is a cross-sectional view of the semiconductor structure after forming an interlevel dielectric layer, according to an embodiment of the present disclosure;

FIG. 11 is a cross-sectional view of the semiconductor structure after forming openings within the interlevel dielectric layer and forming a top metal layer within each of the openings, according to an embodiment of the present disclosure;

FIG. 12 is a cross-sectional view of a semiconductor structure depicting a silicon carbide split gate MOSFET, according to an alternate embodiment of the present disclosure; and

FIG. 13 is a flowchart depicting operational steps for the fabrication of the semiconductor structure, according to an embodiment of the present disclosure.

The drawings are not necessarily to scale. The drawings are merely schematic representations, not intended to portray specific parameters of the invention. The drawings are intended to depict only typical embodiments of the invention. In the drawings, like numbering represents like elements.

### DETAILED DESCRIPTION

Detailed embodiments of the claimed structures and methods are disclosed herein; however, it can be understood that the disclosed embodiments are merely illustrative of the claimed structures and methods that may be embodied in various forms. This invention may, however, be embodied in many different forms and should not be construed as limited to the exemplary embodiments set forth herein. In the description, details of well-known features and techniques may be omitted to avoid unnecessarily obscuring the presented embodiments.

For purposes of the description hereinafter, terms such as “upper”, “lower”, “right”, “left”, “vertical”, “horizontal”, “top”, “bottom”, and derivatives thereof shall relate to the disclosed structures and methods, as oriented in the drawing figures. Terms such as “above”, “overlying”, “atop”, “on top”, “positioned on” or “positioned atop” mean that a first element, such as a first structure, is present on a second element, such as a second structure, wherein intervening elements, such as an interface structure may be present between the first element and the second element. The term “direct contact” means that a first element, such as a first structure, and a second element, such as a second structure, are connected without any intermediary conducting, insulating or semiconductor layers at the interface of the two elements.

In the interest of not obscuring the presentation of embodiments of the present disclosure, in the following detailed description, some processing steps or operations that are known in the art may have been combined together for presentation and for illustration purposes and in some instances may have not been described in detail. In other instances, some processing steps or operations that are known in the art may not be described at all. It should be understood that the following description is rather focused on the distinctive features or elements of various embodiments of the present invention.

SiC is considered attractive for high-voltage power systems due to its large band gap which enables blocking of large voltages with a smaller on resistance. SiC is a crystalline substance capable of enduring very high temperatures that can eliminate the need for device cooling. SiC semiconductor devices can operate at temperatures above 200° C. SiC also has a high breakdown field of about ten times that of silicon, and a higher thermal conductivity of about three times that of silicon. These properties can lead to reductions in weight, energy dissipation and volume at the system level in diverse applications.

One drawback of SiC in MOSFETs integration is that, due to its large band gap, the built-in potential of SiC p/n junction at room temperature can be as high as 2.7 V. This can cause significant conduction loss in third quadrant operation (source-to-drain positive bias) compared to Si MOSFETs. Third quadrant (3rd-quad) operation occurs for a power SiC MOSFET when the current flows from the source to the drain terminal through the body diode or the channel. An alternative includes using a SiC Schottky diode that has a built-in potential of less than 1V. However, since SiC Schottky diodes are not compatible with SiC MOSFETs integration process, a standalone SiC Schottky diode needs to be implemented in this instance which increases the size and cost of the semiconductor chip.

Embodiments of the present disclosure provide a semiconductor device, and a method of making the same, in which a polycrystalline silicon (also referred to as poly-Si or polysilicon)/silicon carbide (SiC) diode is integrated within a SiC MOSFET. According to an embodiment, a trench is formed between the MOSFET's active cell with the trench bottom being implanted periodically using a p-type dopant to provide a shielding effect for the active cell near the surface. The trench bottom remains open allowing the p-type polysilicon to be in contact with the SiC drift region. By doing so, the portion of the active cell without p-shield forms a polysilicon/SiC heterojunction diode with a forward voltage (VF) that is under 1V. As a result, embodiments of the present disclosure can improve 3rd quadrant operation by integrating a Schottky barrier rectifier within the SiC MOSFET. Integration of the Schottky barrier rectifier within the SiC MOSFET optimizes device footprint and reduces manufacturing costs.

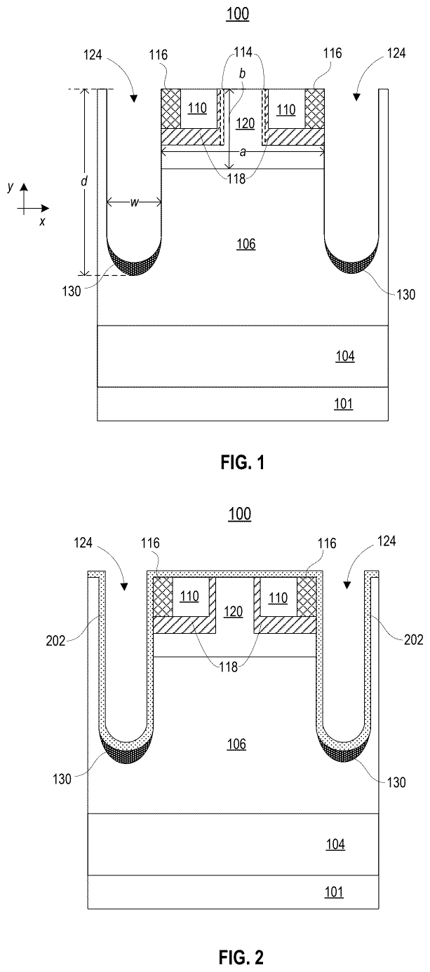

Embodiments by which SiC MOSFETs with an integrated polysilicon/SiC heterojunction diode can be formed is described in detail below by referring to the accompanying drawings in FIGS. 1-13.

Referring now to FIG. 1, a cross-sectional view of a semiconductor structure 100 is shown at an intermediate step during a semiconductor manufacturing process, according to an embodiment of the present disclosure. More particularly, FIG. 1 depicts an intermediate step during the formation of a planar SiC MOSFET with integrated polysilicon-SiC heterojunction diode.

At this step of the manufacturing process, semiconductor structure 100 includes a semiconductor substrate 104 and a drift region 106 disposed above an upper surface of the semiconductor substrate 104. Semiconductor substrate 104 includes a polycrystalline silicon carbide structure of a first conductivity type. The first conductivity type can be p-type or n-type. A dopant concentration of the semiconductor substrate 104 may vary between approximately 1×10¹⁸ cm⁻³ to approximately 1×10¹⁹ cm⁻³. A thickness of the semiconductor substrate 104 may vary from approximately 100 μm to approximately 350 μm, although a thickness less than 100 μm and greater than 350 μm may also be acceptable.

In one or more embodiments, the drift region 106 also includes a polycrystalline silicon carbide structure of the first conductivity type. The drift region 106 can be formed by epitaxial growth by using the semiconductor substrate 104 as seed layer. Terms such as “epitaxial growth and/or deposition” and “epitaxially formed and/or grown” refer to the growth of a semiconductor material on a deposition surface of a semiconductor material, in which the semiconductor material being grown has the same or substantially similar crystalline characteristics as the semiconductor material of the deposition surface.

In some embodiments, the drift region 106 can be formed by chemical vapor deposition (CVD) of the semiconductor material (i.e., SiC). In some embodiments, a dopant concentration of the drift region 106 may be lower than that of the semiconductor substrate 104. For example, the dopant concentration of the drift region 106 may vary between approximately 1×10¹⁵ cm⁻³ to approximately 1×10¹⁷ cm⁻³. Drift region 106 may have a thickness varying from approximately 1 um to approximately 100 um, although a thickness less than 1 um and greater than 100 um may also be acceptable.

According to an embodiment, semiconductor substrate 104 serves as a drain region for the semiconductor structure 100, providing a pathway for current flow. While the drain region is integrated within the semiconductor substrate 104, in some embodiments it can be engineered with distinct doping characteristics or other modifications to meet specific designs, enhance performance or manage thermal properties.

In one or more embodiments, a bottom metal layer 101 located on a bottom surface of the semiconductor substrate 104 forms a drain terminal or drain electrode that provides electrical (ohmic) contact with the semiconductor substrate 104.

According to an embodiment, semiconductor structure 100 further includes a junction field effect transistor (JFET) region 120. In some instances, JFET region 120 may be formed with a higher donor doping of the first conductivity type that can vary between, for example, 1×10¹⁵ cm⁻³ and 1×10¹⁸ cm⁻³. In the depicted embodiment, JFET region 120 includes a horizontal portion “a” and a vertical portion “b”. The horizontal portion a of the JFET region 120 extends between an uppermost surface of the drift region 106 and a bottommost portion of base regions 118. The vertical portion b of the JFET region 120 is laterally bounded by base regions 118. The horizontal portion a of JFET region 120 may have a thickness varying from approximately 1 um to approximately 10 um, while vertical portion b may have a thickness varying from approximately 0 um to approximately 10 um.

Base regions 118 include low-doped semiconductor regions of a second conductivity type. A dopant concentration of base regions 118 can vary between, for example, 1×10¹⁵ cm⁻³ and 1×10¹⁸ cm⁻³. The second conductivity type can be n-type or p-type. For example, in embodiments in which the first conductivity type is n-type, the second conductivity type is p-type. Similarly, in embodiments in which the first conductivity type is p-type, the second conductivity type is n-type. In this embodiment, a channel region 114 is defined within base regions 118 when semiconductor structure 100 is in operation. A length of each channel region 114 is defined by a respective base region 118 and the vertical portion b of the JFET region 120. As may be understood, channel regions 114 are of the second conductivity type.

Each source region 110 is located above and in contact with a respective base region 118, as depicted in FIG. 1. Source regions 110 may include a highly-doped source region of the first conductivity type. A dopant concentration of source regions 110 can vary, for example, between 1×10¹⁹ cm⁻³ and 1×10²¹ cm⁻³. Adjacent to each source region 110 is a body region 116 including a highly doped first semiconductor region of the second conductivity type. Each source region 110 is laterally abutted by a base region 118 and a body region 116.

With continued reference to FIG. 1, a trench 124 is formed within the drift region 106

adjacent to each of the body regions 116 of the semiconductor structure 100. The process of forming the trench 124 may typically involve exposing a pattern on a photoresist layer, transferring the pattern to a hardmask layer (not shown) and then to the drift region 106 using lithography and reactive-ion etching (RIE) processing. In one or more embodiments, a (vertical) depth d of the trench 124 into the drift region 106 may vary between approximately 0.5 um to approximately 2 um, while a width w of trench 124 (as measured in the x-direction) varies between 0.5 um to approximately 2 um. Additionally, in an embodiment, each trench 124 and each source region 110 in the semiconductor structure 100 are separated by a predetermined distance that may vary between approximately 0 um to approximately 5 um.

Each trench 124 exposes a top surface of the drift region 106 at a bottom portion or lower segment of trenches 124. After forming each of the trenches 124, a second semiconductor region 130 can be formed on the top surface of drift region 106 exposed by the lower segment of trench 124.

In one or more embodiments, the second semiconductor region 130 includes a highly-doped

semiconductor region formed by implanting dopants of the second conductivity type on portions of the drift region 106 exposed by trench 124. Accordingly, an interface of the second semiconductor region 130 and the drift region 106 is located on the bottom portion or lower segment of trench 124. Accordingly, a depth of the second semiconductor region 130 within the drift region 106 measured from a bottom portion of the trench 124 may vary between approximately 0.1 um to approximately 1 um, although a depth less than 0.1 um and greater than 3 um may also be acceptable.

The second semiconductor region 130 includes a shield zone of the second conductivity type with thickness and doping values selected to support a desired MOSFET blocking voltage. The second semiconductor region 130 may have a dopant concentration varying between approximately 1×10¹⁷ cm⁻³ and 1×10²⁰ cm⁻³. In embodiments in which the first conductivity type is n-type and the second conductivity type is p-type, the second semiconductor region 130 includes a p-shield zone. In such embodiments, the p-shield zone may have a periodic pattern with a spacing sufficiently small to ensure voltage-blocking.

Referring now to FIG. 2, a cross-sectional view of the semiconductor structure 100 is shown after forming an oxide layer 202 within trench 124, according to an embodiment of the present disclosure.

As depicted in FIG. 2, oxide layer 202 substantially covers opposing vertical sidewalls of drift region 106 exposed by trench 124 and an uppermost surface of the second semiconductor region 130 also exposed by trench 124. Oxide layer 202 may also extend above a top surface of the semiconductor structure 100 that is parallel to semiconductor substrate 104. In one or more embodiments, the oxide layer 202 may be formed by thermal oxidation of an oxide material. In other embodiments, the oxide layer 202 may be formed by conformal deposition of the oxide material. Non-limiting examples of oxide materials to form the oxide layer 202 may include silicon oxide (SiO_{X}), and the like. In an exemplary embodiment, a thickness of the oxide layer 202 may vary between approximately 10 nm to approximately 1,000 nm.

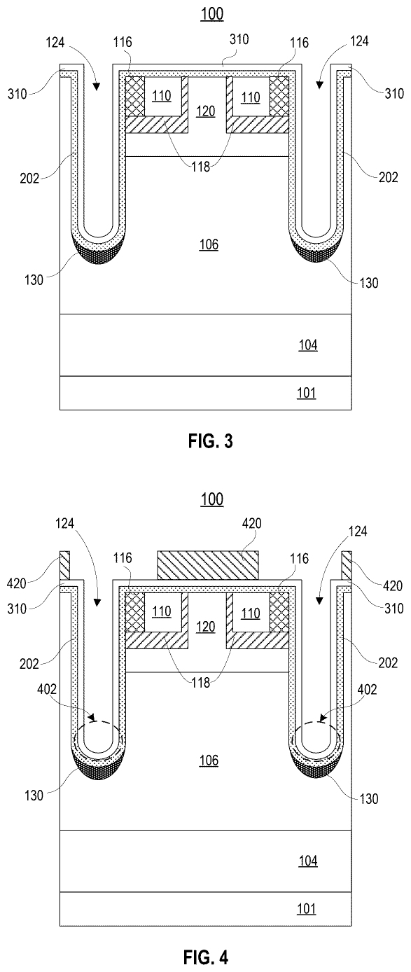

Referring now to FIG. 3, a cross-sectional view of the semiconductor structure 100 is shown after forming a nitride layer 310 above the oxide layer 202, according to an embodiment of the present disclosure.

The nitride layer 310 is disposed directly above oxide layer 202. In one or more embodiments, formation of the nitride layer 310 includes conformally depositing a nitride material (e.g., silicon nitride) using conformal deposition methods including, for example, CVD or atomic layer deposition (ALD). In an exemplary embodiment, a thickness of the nitride layer 310 may vary between approximately 10 nm to approximately 5,000 nm. In one or more embodiments, the nitride layer 310 may function as a hardmask layer during subsequent etching steps, as will be described in detail below.

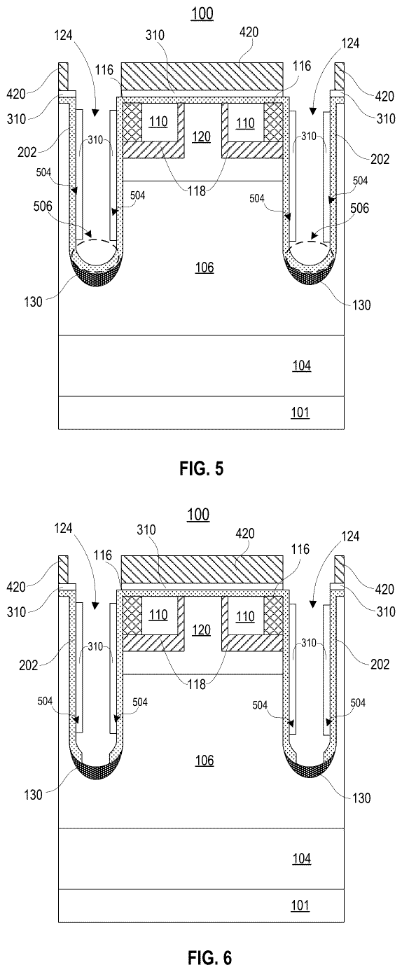

Referring now to FIGS. 4-5 simultaneously, cross-sectional views of the semiconductor structure 100 are shown after forming a photoresist layer 420, patterning the photoresist layer 420 and etching the nitride layer 310, according to an embodiment of the present disclosure.

The photoresist layer 420 is deposited above a (horizontal) surface of the nitride layer 310 parallel to the semiconductor substrate 104. The process of forming and patterning the photoresist layer involves exposing a pattern (not shown) on the photoresist layer 420 and transferring the exposed pattern to the nitride layer 310 using lithography and reactive ion etch (RIE) processing.

An anisotropic etching (e.g., RIE) can then be performed on the semiconductor structure 100 to remove a bottom portion 402 (FIG. 4) of the nitride layer 310. The anisotropic nature of the etching process allows removing bottom portions 402 of the silicon nitride layer 310 located along a lower segment of the trench 124 while keeping vertical portions 504 of the nitride layer 310, as depicted in FIG. 5. Removal of the bottom portions 402 of the nitride layer 310 exposes an area 506 (FIG. 5) of the oxide layer 202 that is in contact with the second semiconductor region 130.

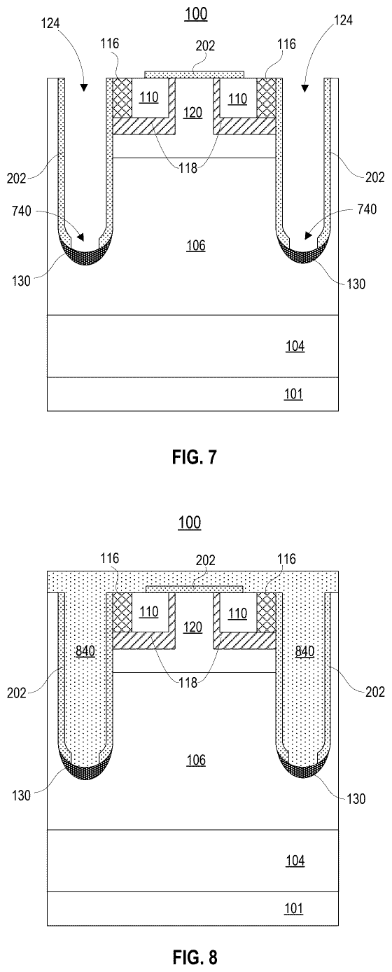

Referring now to FIGS. 6-7 simultaneously, cross-sectional views of the semiconductor structure 100 are shown after removing the area 506 of the oxide layer 202 depicted in FIG. 5 and stripping the nitride layer 310, according to an embodiment of the present disclosure.

In this embodiment, vertical portions 504 of the nitride layer 310 can be used as a hardmask to remove the exposed area 506 (shown in FIG. 5) of the oxide layer 202 located above the second semiconductor region 130. Accordingly, an etching process can be performed on the semiconductor structure 100 to remove the area 506 (FIG. 5) of the oxide layer 202 disposed along the second semiconductor region 130. Preferably, the etching process includes a wet etching process. Wet etch is performed with a solvent (such as an acid) which may be chosen for its ability to selectively dissolve a given material (i.e., the oxide layer 202), while leaving another material relatively intact. A wet etch will generally etch a homogeneous material (e.g., oxide) isotropically.

After etching the area 506 (FIG. 5) of the oxide layer 202, the photoresist layer 420 and nitride layer 310 can be removed from the semiconductor structure 100 using any suitable method known in the art. For example, photoresist layer 420 can be removed using plasma ashing while nitride layer 310 can be removed using RIE.

As shown in FIG. 7, removing the area 506 (FIG. 5) of the oxide layer 202 from the bottom portion of the trench 124 exposes an upper surface of the second semiconductor region 130. Stated differently, removing the bottom portion of the oxide layer 202 corresponding to area 506 (FIG. 5) creates a gap 740 within the oxide layer 202 that is located directly above and exposing the underlying second semiconductor region 130.

It should be noted that a top portion of the oxide layer 202 remains on a top surface of the semiconductor structure 100 parallel to the semiconductor substrate 104. This portion of the oxide layer 202 may electrically isolate a subsequently formed gate electrode from source regions 110 and base regions 118, as will be described in detail below.

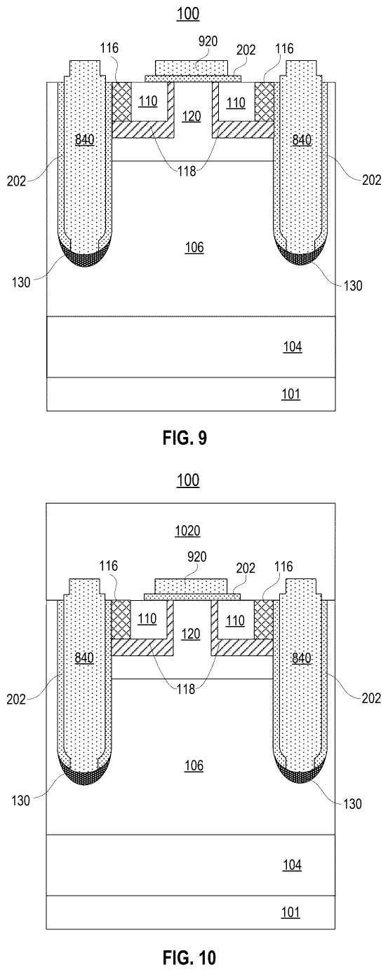

Referring now to FIGS. 8-9 simultaneously, cross-sectional views of the semiconductor structure 100 are shown after depositing and patterning a polysilicon layer 840, according to an embodiment of the present disclosure.

Forming the polysilicon layer 840 includes depositing a polycrystalline silicon material, commonly referred to as polysilicon or poly, within trench 124 (shown in FIG. 7) using any suitable deposition method. The polysilicon layer 840 provides a Schottky contact for the semiconductor structure 100. In one or more embodiments, the polysilicon layer 840 includes a layer of heavily-doped polysilicon of the second conductivity type. For example, in an embodiment, the polysilicon layer 840 may have a dopant concentration varying between approximately 1×10¹⁸ cm⁻³ and approximately 1×10²¹ cm⁻³.

The polysilicon layer 840 may substantially fill trench 124 (shown in FIG. 7) and extend beyond an uppermost surface of the semiconductor structure 100. According to an embodiment, a bottom portion of the polysilicon layer 840 is above and in direct contact with the second semiconductor region 130, as depicted in the figures. Stated differently, the gap 740 (shown in FIG. 7) in the oxide layer 202 allows the bottom portion of the polysilicon layer 840 formed within trench 124 (shown in FIG. 7) to be in electrical contact with the second semiconductor region 130 for providing a polysilicon/SiC heterojunction diode. Such polysilicon/SiC heterojunction diode provides a Schottky barrier rectifier integrated within the semiconductor structure 100.

In one or more embodiments, upper portions of the polysilicon layer 840 can be patterned to form a gate region including gate electrode 920. Gate electrode 920 extends, at least partially, over the oxide layer 202. The oxide layer 202 electrically isolates the gate electrode 920 from source regions 110 and base regions 118. The process of patterning the polysilicon layer 840 includes forming a photoresist layer (not shown) above the polysilicon layer 840 exposing a pattern on the photoresist layer, transferring the pattern to a hardmask layer (not shown) and then to the polysilicon layer 840 using lithography and RIE processing.

Referring now to FIG. 10, a cross-sectional view of the semiconductor structure 100 is shown after forming an interlevel dielectric layer (ILD) 1020, according to an embodiment of the present disclosure.

The ILD layer 1020 is disposed above an upper surface of semiconductor structure 100. In one or more embodiments, ILD layer 1020 fills voids and electrically isolates active regions within the semiconductor structure 100. The ILD layer 1020 can be formed by, for example, conformal deposition (e.g., CVD) of a dielectric material. Non-limiting examples of dielectric materials to form ILD layer 1020 may include silicon oxide, silicon nitride, hydrogenated silicon carbon oxide, silicon based low-k dielectrics, flowable oxides, porous dielectrics, or organic dielectrics including porous organic dielectrics.

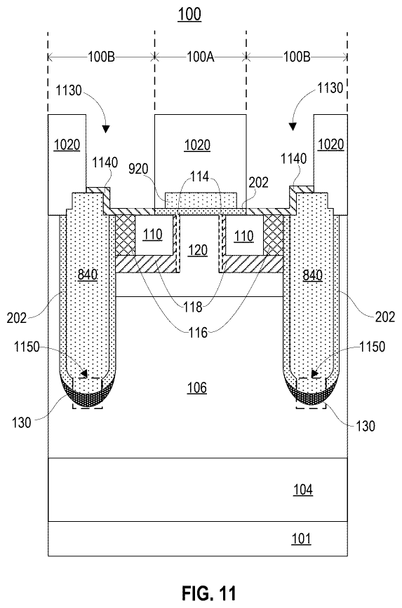

Referring now to FIG. 11, a cross-sectional view of the semiconductor structure 100 is shown after forming openings 1130 within ILD layer 1020 and a top metal layer 1140 within each of the openings 1130, according to an embodiment of the present disclosure.

In this embodiment, openings 1130 are formed within the ILD layer 1020 using patterning techniques. Openings 1130 expose top portions of the polysilicon layer 840, body regions 116, and source regions 110. The top metal layer 1140 is deposited on the exposed top portions of the polysilicon layer 840, body regions 116 and source regions 110, as depicted in the figure. The top metal layer 1140 provides a source terminal that electrically contacts source regions 110, body regions 116 and polysilicon layer 840.

According to an embodiment, an upper surface of the semiconductor structure 100 includes a first region 100A and a second region 100B located on opposite sides of the first region 100A. The first region 100A of the semiconductor structure 100 includes a transistor formation region while each of the second regions 100B adjacent to the first region 100A includes a Schottky barrier diode formation region. In one or more embodiments, the first region 100A includes a pair of channel regions 114 of a second conductivity type opposite to the first conductivity type formed on the drift region 106, a pair of source regions 110 of the first conductivity type formed on the pair of channel regions 114, and a gate electrode 920 formed on the drift region 106 via a gate insulating film (e.g., oxide layer 202) such that the gate electrode 920 is located between the pair of source regions 110.

In one or more embodiments, each of the second regions 100B adjacent to the first region 100A includes a trench 124 (as shown in FIG. 7) within the drift region 106, an oxide layer 202 (i.e., an insulating film) lining a side surface of trench 124 (FIG. 7), a polysilicon layer 840 deposited within the trench 124 and above the oxide layer 202 to form a Schottky electrode, and a second semiconductor region 130 of the second conductivity type formed within drift region 106, such that the second semiconductor region 130 extends to cover a bottom surface of the trench 124 (as depicted in FIG. 7).

It should be noted that formation of gap 740 after removal of the oxide layer 202 from the bottom portion of trench 124 (depicted in FIG. 7), allows the deposited polysilicon layer 840 to be in direct contact with the second semiconductor region 130 forming a polysilicon/SiC heterojunction diode with a forward voltage (VF) that is under 1V. More particularly, a junction or contact area 1150 between a metal (e.g., polysilicon from polysilicon layer 840) and a semiconductor material (e.g., SiC from the second semiconductor region 130 disposed within drift region 106) forms a Schottky barrier rectifier (or simply Schottky diode) within the semiconductor structure 100. Integration of the Schottky barrier rectifier within a SiC MOSFET may improve 3rd quadrant operation, optimize device footprint and reduce manufacturing costs.

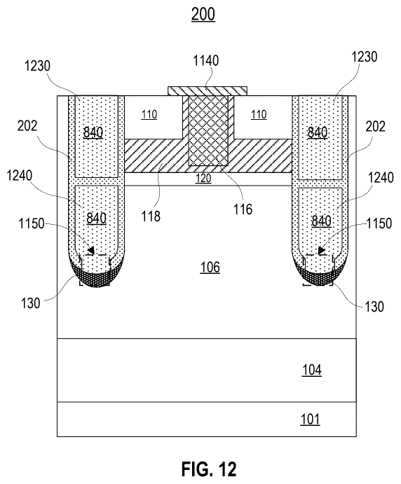

In the depicted embodiment semiconductor structure 100 includes a planar SiC MOSFET. However, it should be noted that embodiments of the present disclosure can be applied to other SiC MOSFET configurations. For example, in some embodiments, the semiconductor structure 100 may include a trench SiC MOSFET (not shown) or, in other embodiments, the semiconductor structure 100 may include a SiC split gate (SG) MOSFET similar to the one described below with reference to FIG. 12.

Referring now to FIG. 12, a semiconductor structure 200 including a SiC SG MOSFET configuration is shown, according to another embodiment of the present disclosure.

For illustration purposes only, without intent of limitation, the components of semiconductor structure 200 are labeled with the same reference numerals used in FIGS. 1-11, as they are analogous to those in semiconductor structure 100. It is important to note, however, that the components of semiconductor structure 200 are configured differently to achieve a SiC SG MOSFET.

In this embodiment, the polysilicon layer 840 is divided into an upper part 1230 and a lower part 1240. The upper part 1230 and the lower part 1240 are separated from one another by oxide layer 202, as shown in FIG. 12. Accordingly, the upper part 1230 of the polysilicon layer 840 serves as the main gate electrode for controlling channel regions 114, while the lower part 1240 serves as the Schottky electrode.

Similar to semiconductor structure 100, the Schottky electrode (lower part 1240) is in direct contact with the second semiconductor region 130 providing the polysilicon/SiC heterojunction diode explained above with reference to FIG. 11. Thus, the embodiments described above with reference to FIGS. 1-11 may equally apply to a SiC SG MOSFET device. In this case, the contact area 1150 between the lower part 1240 of the polysilicon layer 840 and the SiC from the second semiconductor region 130 located within drift region 106 forms the Schottky barrier rectifier within the semiconductor structure 200.

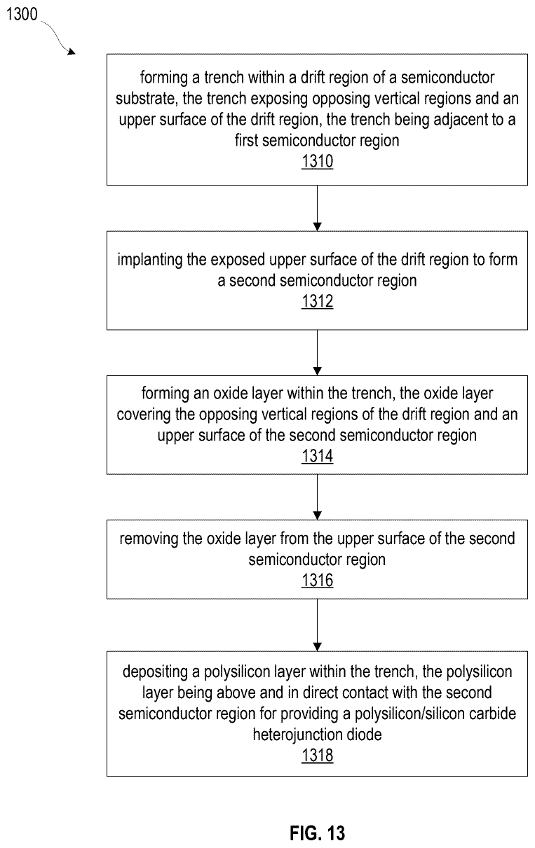

Referring now to FIG. 13, a flowchart 1300 sets forth operational steps for the fabrication of the semiconductor structure 100 described above with reference to FIGS. 1-12, according to an embodiment of the present disclosure.

The fabrication process starts at step 1310 in which a trench is formed within a drift region of a semiconductor substrate. The trench exposes opposing vertical regions and an upper surface of the drift region. The trench is located adjacent to a first semiconductor region. Both the semiconductor substrate and the drift region include a doped semiconductor material of a first conductivity type. The semiconductor material includes silicon carbide.

At step 1312, the exposed upper surface of the drift region is implanted to form a (doped) second semiconductor region. The first semiconductor region and the second semiconductor region are of a second conductivity type opposite to the first conductivity type. In some embodiments, the first conductivity type is n-type and the second conductivity type is p-type. In other embodiments, the first conductivity type is p-type and the second conductivity type is n-type.

At step 1314, the process continues by forming an oxide layer within the trench. The oxide layer covers the opposing vertical regions of the drift region and an upper surface of the second semiconductor region.

At step 1316, an etching process is conducted to selectively remove the oxide layer from the upper surface of the second semiconductor region. The process of selectively removing the oxide layer includes forming a nitride layer above and in direct contact with the oxide layer, selectively removing a bottom portion of the nitride layer, where selectively removing the bottom portion of the nitride layer exposes portions of the oxide layer in contact with the second semiconductor region, and using the remaining vertical portions of the nitride layer as a hardmask, selectively removing the exposed portions of the oxide layer in contact with the second semiconductor region.

Finally, at step 1318, a polysilicon layer is deposited within the trench. The polysilicon layer is disposed above and in direct contact with the second semiconductor region for providing a polysilicon/silicon carbide heterojunction diode or Schottky barrier rectifier. The process of depositing the polysilicon layer further includes patterning portions of the polysilicon layer extending above the trench to form a gate electrode with the gate electrode disposed, at least partially, above a top portion of the oxide layer.

The process of forming the semiconductor structure 100 further includes forming a JFET region extending vertically between channel regions and horizontally below well or base regions in the semiconductor substrate, forming a source region in contact with each channel region and the first semiconductor region, forming a top metal layer in electric contact with the polysilicon layer, the first semiconductor layer, and the source region, the top metal layer proving a source terminal, and forming a bottom metal layer in electric contact with a bottom surface of the semiconductor substrate, the bottom layer proving a drain terminal.

### EXAMPLES

Example 1. A method of forming a semiconductor structure, comprising:
forming a trench within a drift region of a semiconductor substrate, the drift region including silicon carbide, the trench exposing opposing vertical regions and an upper surface of the drift region, the trench being adjacent to a first semiconductor region;
implanting the exposed upper surface of the drift region to form a second semiconductor region;
forming an oxide layer within the trench, the oxide layer covering the opposing vertical regions of the drift region and an upper surface of the second semiconductor region;
removing the oxide layer from the upper surface of the second semiconductor region; and
depositing a polysilicon layer within the trench, the polysilicon layer being above and in direct contact with the second semiconductor region for providing a polysilicon/silicon carbide heterojunction diode.

Example 2. The method according to Example 1, wherein the semiconductor substrate and the drift region are of a first conductivity type.

Example 3. The method according to Example 1, wherein the first semiconductor region and the second semiconductor region are of a second conductivity type opposite to the first conductivity type.

Example 4. The method according to Example 3, wherein the first conductivity type is n-type and the second conductivity type is p-type.

Example 5. The method according to Example 3, wherein the first conductivity type is p-type and the second conductivity type is n-type.

Example 6. The method according to Example 1, further comprising:
forming a nitride layer above and in direct contact with the oxide layer; and
selectively removing a bottom portion of the nitride layer, wherein selectively removing the bottom portion of the nitride layer exposes portions of the oxide layer in contact with the second semiconductor region.

Example 7. The method according to Example 6 further comprising:
using remaining vertical portions of the nitride layer as a hardmask, selectively removing the exposed portions of the oxide layer in contact with the second semiconductor region.

Example 8. The method according to Example 1 further comprising:
patterning the polysilicon layer to form a gate electrode, the gate electrode extending, at least partially, above the oxide layer.

Example 9. The method according to Example 1 further comprising:
forming a JFET region extending vertically between channel regions and horizontally bellow base regions in the semiconductor substrate; and
forming a source region in contact with each channel region and the first semiconductor region.

Example 10. The method according to Example 1 further comprising:
forming a top metal layer in electric contact with the polysilicon layer, the first semiconductor layer, and the source region, the top layer proving a source terminal.

Example 11. The method according to Example 1 further comprising:
forming a bottom metal layer in electric contact with a bottom surface of the semiconductor substrate, the bottom layer proving a drain terminal.

Example 12. A method of forming a semiconductor structure, comprising:
forming a semiconductor substrate of a first conductivity type, the semiconductor substrate having an upper surface and a bottom surface, the semiconductor substrate including polycrystalline silicon carbide;
forming a drift region of the first conductivity type on the upper surface of the semiconductor substrate;
forming, on a first region of the upper surface of the semiconductor substrate, a formation region of a transistor; and
forming, on a second region of the upper surface of the semiconductor substrate adjacent to the first region, a formation region of a Schottky barrier diode.

Example 13. The method according to Example 12, wherein forming the first region includes:
forming a pair of channel regions of a second conductivity type opposite to the first conductivity type, the pair of channel regions being located within the drift region;
forming a pair of source regions of the first conductivity type, the pair of source regions being above and in contact with the pair of channel regions; and
forming a gate electrode above an oxide layer, wherein the pair of source regions are adjacent to the gate electrode.

Example 14. The method according to Example 12, wherein forming the second region adjacent to the first region includes:
forming a polysilicon layer within a trench on the drift region, the polysilicon layer providing a Schottky electrode;
forming an oxide layer on opposing vertical sidewalls of the polysilicon layer, the oxide layer having a gap located on a bottom surface of the polysilicon layer;
forming a second semiconductor region of the second conductivity type within the drift region, wherein the gap located on the bottom surface of the polysilicon layer allows the polysilicon layer to contact the second semiconductor region for providing a polysilicon/SiC heterojunction diode.

Example 15. The method according to Example 14, wherein the Schottky electrode and the second semiconductor region are electrically connected at a bottom portion of the trench.

Example 16. The method according to Example 14, wherein the Schottky electrode and the second semiconductor region provide a Schottky barrier rectifier located at the bottom portion of the trench.

Example 17. The method according to Example 14, wherein the Schottky electrode and the pair of source regions are electrically connected to a source terminal.

Example 18. The method according to Example 14, wherein the Schottky electrode includes a layer of the polycrystalline silicon carbide.

Example 19. A method of forming a semiconductor structure, comprising:
forming a drift region of a first conductivity type on an upper surface of a semiconductor substrate of the first conductivity type, the drift region and the semiconductor substrate including polycrystalline silicon carbide;
forming a trench within the drift region;
forming a polysilicon layer within the trench;
forming an oxide layer along opposing vertical sidewalls of the polysilicon layer and between an upper part of the polysilicon layer and a lower part of the polysilicon layer, a bottom portion of the oxide layer including a gap; and
forming a second doped semiconductor region within the drift region, wherein the gap on the bottom portion of the oxide layer allows the lower part of the polysilicon layer to contact the doped semiconductor region.

Example 20. The method according to Example 19, wherein the upper part of the polysilicon layer comprises a gate electrode and the lower part of the polysilicon layer comprises a Schottky electrode, wherein the oxide layer electrically separates the gate electrode from the Schottky electrode.

The terminology used herein is for the purpose of describing particular embodiments only and is not intended to be limiting of the disclosure. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. “Optional” or “optionally” means that the subsequently described event or circumstance may or may not occur, and that the description includes instances where the event occurs and instances where it does not.

Spatially relative terms, such as “inner,” “outer,” “beneath,” “below,” “lower,”“above,” “upper,” “top,” “bottom,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” may encompass both an orientation of above and below. The device may be otherwise oriented (rotated 90 degrees or at other orientations) and the spatially relative descriptors used herein interpreted accordingly.

Approximating language, as used herein throughout the specification and claims, may be applied to modify any quantitative representation that could permissibly vary without resulting in a change in the basic function to which it is related. Accordingly, a value modified by a term or terms, such as “about”, “approximately” and “substantially”, are not to be limited to the precise value specified. In at least some instances, the approximating language may correspond to the precision of an instrument for measuring the value. Here and throughout the specification and claims, range limitations may be combined and/or interchanged, such ranges are identified and include all the sub-ranges contained therein unless context or language indicates otherwise. “Approximately” as applied to a particular value of a range applies to both values, and unless otherwise dependent on the precision of the instrument measuring the value, may indicate +/−10% of the stated value(s).

The descriptions of the various embodiments of the present invention have been presented for purposes of illustration, but are not intended to be exhaustive or limited to the embodiments disclosed. Many modifications and variations will be apparent to those of ordinary skill in the art without departing from the scope of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor structure comprising:
a semiconductor substrate of a first conductivity type having an upper surface and a bottom surface, the semiconductor substrate including polycrystalline silicon carbide;
a drift region of the first conductivity type located on the upper surface of the semiconductor substrate;
a first region of the upper surface of the semiconductor substrate including a formation region of a transistor; and
a second region of the upper surface of the semiconductor substrate, adjacent to the first region, including a formation region of a Schottky barrier diode.

2. The semiconductor structure of claim 1, wherein the first region includes:
a pair of channel regions of a second conductivity type opposite to the first conductivity type, the pair of channel regions located within the drift region;
a pair of source regions of the first conductivity type disposed above and in contact with the pair of channel regions; and
a gate electrode disposed above a first portion of an oxide layer, wherein the pair of source regions are adjacent to the gate electrode.

3. The semiconductor structure of claim 2, wherein the second region adjacent to the first region includes:
a polysilicon layer within a trench on the drift region, the polysilicon layer providing a Schottky electrode;
a second portion of the oxide layer disposed on opposing vertical sidewalls of the polysilicon layer, the second portion of the oxide layer having a gap located on a bottom surface of the polysilicon layer; and
a second semiconductor region of a second conductivity type located within the drift region, wherein the gap in the second portion of the oxide layer allows the bottom surface of the polysilicon layer to contact the second semiconductor region for providing a polysilicon/SiC heterojunction diode.

4. The semiconductor structure of claim 3, wherein the Schottky electrode and the second semiconductor region are electrically connected at a bottom portion of the trench.

5. The semiconductor structure of claim 4, wherein the Schottky electrode and the second semiconductor region provide a Schottky barrier rectifier located at the bottom portion of the trench.

6. The semiconductor structure of claim 3, wherein the Schottky electrode and the pair of source regions are electrically connected to a source terminal.

7. The semiconductor structure of claim 3, wherein the Schottky electrode comprises a layer of the polycrystalline silicon carbide.

8. The semiconductor structure of claim 4, wherein a depth of the second semiconductor region within the drift region from the bottom portion of the trench varies between 0.1 um to 5 um.

9. The semiconductor structure of claim 3, wherein a dopant concentration of the second semiconductor region is more than 1×10¹⁷ cm⁻³ and less than 1×10²⁰ cm⁻³.

10. The semiconductor structure of claim 3, wherein the trench and the pair of source regions are separated by a predetermined distance varying between 0 um to 5 um.

11. The semiconductor structure of claim 3, further comprising:
a first semiconductor region located between at least one source region of the pair of source regions and the trench; and
a drain terminal disposed on a bottom surface of the semiconductor substrate.

12. A semiconductor structure comprising:
a drift region of a first conductivity type located on an upper surface of a semiconductor substrate of the first conductivity type, the drift region and the semiconductor substrate including polycrystalline silicon carbide;
a JFET region of the first conductivity type disposed above the drift region, the JFET region including a vertical portion and a horizontal portion;
a pair of channel regions disposed along the vertical portion and the horizontal portion of the JFET region;
a pair of source regions adjacent to the JFET region, wherein each source region is abutted by a respective channel region and a first doped semiconductor region; and
a Schottky electrode adjacent to the first doped semiconductor region, wherein an oxide layer electrically separates the Schottky electrode from the first doped semiconductor region, wherein the oxide layer covers vertical opposing sidewalls of the Schottky electrode and a gap located on a bottom portion of the oxide layer allows the Schottky electrode to contact a second doped semiconductor region located within the drift region.

13. The semiconductor structure of claim 12, wherein the Schottky electrode adjacent to the first doped semiconductor region comprises:
a layer of polycrystalline silicon carbide substantially filling a trench within the drift region.

14. The semiconductor structure of claim 13, wherein the Schottky electrode being in contact with the second doped semiconductor region provides a Schottky barrier rectifier integrated within the semiconductor structure.

15. The semiconductor structure of claim 12, wherein the Schottky electrode and the pair of source regions are electrically connected to a source terminal.

16. The semiconductor structure of claim 12, further comprising:
a drain terminal disposed on a bottom surface of the semiconductor substrate.

17. A semiconductor structure comprising:
a drift region of a first conductivity type located on an upper surface of a semiconductor substrate of the first conductivity type, the drift region and the semiconductor substrate including polycrystalline silicon carbide;
a trench extending into the drift region;
a polysilicon layer disposed within the trench;
an oxide layer disposed on opposing vertical sidewalls of the polysilicon layer and between an upper part of the polysilicon layer and a lower part of the polysilicon layer, a bottom portion of the oxide layer including a gap; and
a second doped semiconductor region within the drift region, wherein the gap on the bottom portion of the oxide layer allows the lower part of the polysilicon layer to contact the doped semiconductor region.

18. The semiconductor structure of claim 17, wherein the upper part of the polysilicon layer comprises a gate electrode and the lower part of the polysilicon layer comprises a Schottky electrode, wherein the oxide layer electrically separates the gate electrode from the Schottky electrode.

19. The semiconductor structure of claim 18, wherein the Schottky electrode being in contact with the doped semiconductor region provides a Schottky barrier rectifier integrated within the semiconductor structure.

20. The semiconductor structure of claim 17, further comprising:
a first doped semiconductor region located between a pair of channel regions and above a base region, the base region disposed above a JFET region, wherein the trench is adjacent to at least one channel region of the pair of channel regions;
a pair of source regions disposed above a respective channel region of the pair of channel regions;
a source terminal disposed above the pair of source regions; and
a drain terminal disposed on a bottom surface of the semiconductor substrate.
